(19) United States
(12) Patent Application Publication
(10) Pub. No.: US 2008/0266983 A1
(43) Pub. Date: Oct. 30, 2008

(54) FLASH MEMORY DEVICE AND METHOD OF ERASING FLASH MEMORY DEVICE

(75) Inventors: Jin-Kook KIM, Gunpo-si (KR); Jin-Yub LEE, Seocho-gu (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/025,117

(22) Filed: Feb. 4, 2008

(30) Foreign Application Priority Data
Apr. 26, 2007 (KR) 10-2007-0040966

(51) Int. Cl. G11C 16/16

(52) U.S. Cl. 365/185.33

(57) ABSTRACT

A flash memory device includes a memory cell array, a bulk voltage generator and a controller. The memory cell array is formed in a bulk area and including memory cells arranged in rows and columns. The bulk voltage generator is configured to supply a bulk voltage to the bulk area. The controller is configured to control the bulk voltage generator to vary an erase time based on a time when the bulk voltage reaches a target voltage.

### CROSS-REFERENCE TO RELATED APPLICATIONS

A claim of priority is made to Korean Patent Application No. 10-2007-0040966, filed on Apr. 26, 2007, the subject matter of which is hereby incorporated by reference.

### BACKGROUND

The present invention relates to semiconductor memories, and more particularly, to a flash memory device and a method of erasing a flash memory device.

Semiconductor memories are considered to be among the most vital microelectronic components of digital logic system design, for example, in computers and microprocessor-based applications ranging from satellite to customer electronics. Therefore, advances in fabrication of semiconductor memories, including process enhancements and technology developments through scaling for higher densities and faster speeds, help establish performance standards for other digital logic families.

Semiconductor memory devices are characterized as volatile random access memory (RAM) devices or nonvolatile read-only memory (ROM) devices. In RAMs, the logical information is stored either by setting up logical states of a bistable flip-flop, such as in a static random access memory (SRAM), or through charging a capacitor, such as in a dynamic random access memory (DRAM). In either case, data are stored and can be read out as long as power is applied. The data are lost, though, when the power is turned off. Hence, they are called volatile memories.

Nonvolatile semiconductor memory devices, such as masked ROM (MROM), programmable ROM (PROM), erasable programmable ROM (EPROM), and electrically erasable programmable ROM (EEPROM), are capable of retaining stored data even when power is off. The nonvolatile memory data storage mode may be permanent or reprogrammable, depending upon the fabrication technology used. Nonvolatile memories are used for program and microcode storage in a wide variety of applications in various industries, such as computer, avionics, telecommunications, and consumer electronics. A combination of single-chip volatiles and nonvolatile memory storage modes is also available in devices, such as nonvolatile SRAM (nvRAM), for use in systems that require fast, reprogrammable nonvolatile memory. In addition, many special memory architectures have evolved to contain additional logic circuitry to optimize performance for application-specific tasks.

Among the nonvolatile semiconductor memories, MROMs, PROMs and EPROMs are inconvenient for general users to renew storage contents because they are not configured for erasing and writing. In contrast, since EEPROMs are capable of electrically erasing and writing data relatively easily, they have been incorporated for use by numerous applications, such as system programming, which require continuous updating and auxiliary storage.

One example of an EEPROM nonvolatile memory device is a flash memory device, in which multiple memory regions may be erased or programmed by one program operation. In contrast, a conventional EEPROM enables only one memory region to be erased or programmed at a time, which means that the flash memory device operates at fast and effective speeds when systems using flash memory devices read and write with respect to multiple memory regions. All types of flash memory and EEPROM typically wear out after a specific number of erase operations, e.g., due to wearing out of an insulation film surrounding a charge storage means used to store data.

Memory cells may be erased through various methods. For example, memory cells may be erased by driving a bulk area with a first erase voltage and word lines with a second erase voltage, where the first erase voltage (e.g., 20V or 10V) is higher than the second erase voltage (e.g., 0V or −7V), which has a positive or negative voltage. In general, an erase operation may be performed during a predetermined time period (referred to as an erase time). Therefore, the first erase voltage and the second erase voltage may be respectively applied to the bulk area and the word lines during the erase time.

However, the conventional method of respectively applying the first erase voltage and the second erase voltage to the bulk area and the word lines may cause problems. One problem is that the erase time may be constantly maintained, regardless of variable conditions affecting particular flash memory devices. For example, the performance of a pump circuit (e.g., the pumping capacity) that generates an erase voltage for an erase operation may change depending upon process, voltage and temperature variations of the flash memory devices. For this reason, the erase time may be determined on the basis of a possible worst case scenario. Therefore, a constant erase time, which may be relatively long to cover various adverse conditions, may cause excessive stress when a particular memory cell requires a relatively short time to increase an erase voltage to a target level.

### SUMMARY OF THE INVENTION

One aspect of the present invention provides a method of erasing a flash memory device. The method includes driving with a bulk voltage a bulk area of the flash memory device in which memory cells are formed; detecting when the bulk voltage reaches a target voltage; and terminating the driving of the bulk area following a time period after the bulk voltage reaches the target voltage.

Another aspect of the present invention provides a flash memory device, which includes a memory cell array, a bulk voltage generator and a controller. The memory cell array is formed in a bulk area and includes memory cells arranged in rows and columns. The bulk voltage generator is configured to supply a bulk voltage to the bulk area. The controller is configured to control the bulk voltage generator to vary a total erase time based on a time required for the bulk voltage to reach a target voltage. The bulk voltage generator may generate a detection signal indicating whether the bulk voltage reaches the target voltage.

Another aspect of the present invention provides a memory card, which includes a flash memory device and a memory controller configured to control the flash memory device. The flash memory device includes a memory cell array formed in a bulk area and including memory cells arranged in rows and columns; a bulk voltage generator configured to supply a bulk voltage to the bulk area; and control logic configured to control the bulk voltage generator to vary an erase time based on a time required for the bulk voltage to reach a target voltage.

### BRIEF DESCRIPTION OF THE FIGURES

Non-limiting and non-exhaustive embodiments of the present invention will be described with reference to the following drawings, in which like reference numerals refer to like parts throughout the various figures unless otherwise specified.

FIG. 1 is a block diagram showing a flash memory device, according to exemplary embodiments of the present invention.

FIG. 2 is a block diagram showing control logic illustrated in FIG. 1, according to exemplary embodiments of the present invention.

FIG. 3 is a timing diagram showing an erase operation of a flash memory device, according to exemplary embodiments of the present invention.

FIG. 4 is a diagram showing erase voltages in erase operations of flash memory devices, according to exemplary embodiments of the present invention.

FIG. 5 is a block diagram showing a flash memory device, according to other exemplary embodiments of the present invention.

FIG. 6 is a block diagram showing a memory system, according to exemplary embodiments of the present invention.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

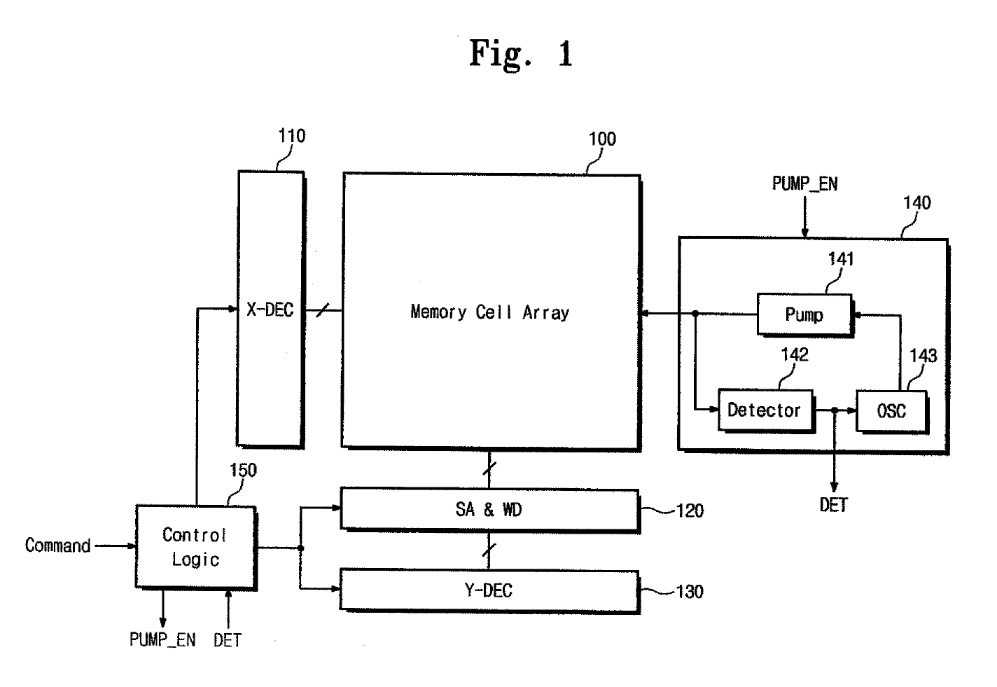

FIG. 1 is a block diagram showing a flash memory device, according to exemplary embodiments of the present invention, capable of adjusting an erase time. The flash memory device according to the embodiments is a NAND flash memory device. However, the present description may be applied to other types of memory devices, such as MRAM, PRAM, Ferroelectric RAM (FRAM), CTF flash memories, NOR flash memories, and the like.

Referring to FIG. 1, an exemplary flash memory device includes a memory cell array 100, a row decoder circuit 110, a sense amplifier and write driver circuit 120, a bulk voltage generator circuit 140, and control logic 150.

The memory cell array 100 stores 1-bit and/or N-bit data information (where N is an integer greater than or equal to 2), and includes memory blocks, each of which has memory cells arranged in rows and columns (not shown). The memory blocks may be formed within a bulk area (e.g., pocket P-well), for example. The row decoder circuit (X-DEC) 110 may be controlled by the control logic 150 to select a memory block and to drive word lines in the selected memory block with word line voltages (e.g., program, read, pass, and erase voltages). The sense amplifier and write driver circuit 120 operates in response to the control of the control logic 150 and acts as a sense amplifier or a write driver based on an operation mode. The sense amplifier and write driver circuit 120 may be referred to as a page buffer. The column decoder circuit (Y-DEC) 130 may provide a data transfer path between the sense amplifier and write driver circuit 120 and an external system (e.g., a memory controller) in response to the control of the control logic 150.

The bulk voltage generator circuit 140 may produce a bulk voltage in response to the control of the control logic 150. For example, the bulk voltage generator circuit 140 may generate the bulk voltage in response to activation of a pump enable signal PUMP_EN from the control logic 150, and generate a detection signal DET when the bulk voltage reaches its target level. In an alternative embodiment, the bulk voltage generator circuit 140 may generate the detection signal DET throughout the time during which it receives the pump enable signal PUMP_EN, and then stop generating the detection signal DET when the bulk voltage reaches its target level, thus indicating that the target level has been reached. Alternatively, the detection signal DET may indicate the voltage level of the bulk voltage generated by the bulk voltage generator 140, which also enables elements that receive the detection signal DET (e.g., control logic 150 and oscillator 143, discussed below) to determine when the target level has been reached based on the detection signal DET.

The bulk voltage may be applied to a bulk area of the memory cell array 100 as an erase voltage. The bulk voltage may have a high voltage level (e.g., 20V) in an erase operation. However, the bulk voltage may be varied according to an erase bias condition.

The bulk voltage generator circuit 140 may include a pump 141, a detector 142, and an oscillator 143. The pump 141 may perform a pumping operation and generate the bulk voltage, in response to an oscillation signal from the oscillator 143, and detect when the bulk voltage reaches its target level. The detector 142 may generate the detection signal DET, for example, when the bulk voltage reaches its target level or throughout the time when the voltage generator circuit 140 receives the pump enable signal PUMP_EN, depending on the embodiment.

As stated above, the detection signal DET may indicate the voltage level of the bulk voltage being generated. Accordingly, the oscillator 143 may produce the oscillation signal in response to the detection signal DET. For example, when the detection signal DET indicates that the bulk voltage has not yet reached its target level (or when the oscillator 143 has not yet received the detection signal DET), the oscillator 143 continues to generate the oscillation signal, causing the pumping operation of the pump 141 to continue, increasing the voltage level. When the detection signal DET indicates that the bulk voltage reaches its target level, the oscillator 143 stops generating the oscillation signal, causing the pumping operation of the pump 141 to stop. Once the pumping operation has stopped, the voltage generator circuit 140 maintains the bulk voltage at the target level until it is discharged, as discussed below.

Continuing to refer to FIG. 1, the control logic 150 may control an overall operation of the flash memory device. For example, the control logic 150 may control an erase operation, so that a total erase time is varied according to a pumping capacity of the bulk voltage generator circuit 140 in the erase operation. The control logic 150 may activate the pump enable signal PUMP_EN, for example, when an erase command is received. This enables a bulk voltage from the bulk voltage generator circuit 140 to be applied to the bulk area. At this time, the control logic 150 may control the row decoder circuit 110, so that word lines in a memory block to be erased are driven with an erase voltage (e.g., 0V). The control logic 150 may determine a termination point of time of the erase operation in response to the detection signal DET from the bulk voltage generator circuit 140. For example, when the detection signal DET indicates that the bulk voltage reaches its target level, the control logic 150 may terminate the erase operation after a given amount of time elapses.

As understood from the above description, the erase operation may be terminated once a bulk voltage reaches a target level and a given amount of time elapses after the bulk voltage reaches the target level. Accordingly, since the time it takes for the bulk voltage to reach its target level may be different in flash memory devices, it is possible to optimize an erase time of respective flash memory devices, according to the various embodiments.

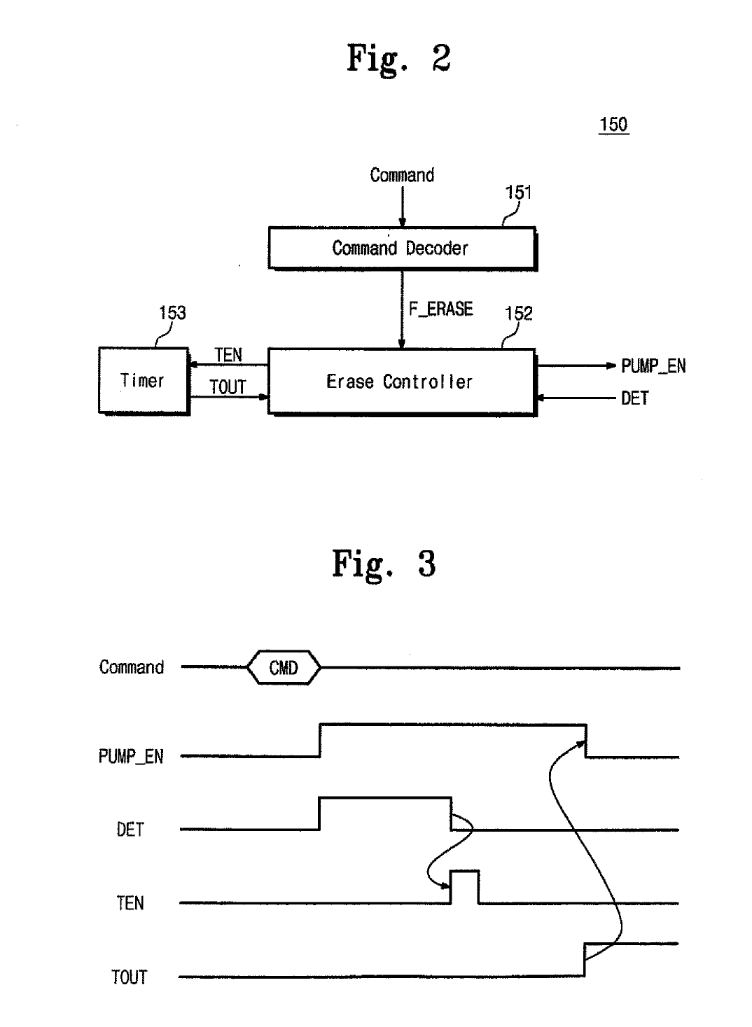

FIG. 2 is a block diagram showing control logic illustrated in FIG. 1, according to exemplary embodiments of the present invention.

Referring to FIG. 2, the control logic 150 may include a command decoder 151, an erase controller 152, and a timer 153. The command decoder 151 may parse an input command and produce a flag signal according to a parsing result. For example, when an erase command is received, the command decoder 151 may generate a flag signal F_ERASE indicating an erase operation. The timer 153 may operate in response to a timer enable signal TEN from the erase controller 152 and output a timer end signal TOUT after a given erase time period elapses. The erase controller 152 may activate the pump enable signal PUMP_EN in response to the flag signal F_ERASE signal.

As described above, the bulk voltage generator circuit 140 in FIG. 1 starts to generate the bulk voltage in response to activation of the pump enable signal PUMP_EN by the control logic 150. The erase controller 152 may activate the timer enable signal TEN to begin a predetermined erase time period in response to the detection signal DET from the bulk voltage generator circuit 140. The erase controller 152 may inactivate the pump enable signal PUMP_EN in response to the timer end signal TOUT from the timer 153 after the predetermined erase time period. As the pump enable signal PUMP_EN is inactivated, the bulk voltage generator circuit 140 in FIG. 1 is inactivated. That is, an erase operation is terminated.

FIG. 3 is a timing diagram illustrating an erase operation of a flash memory device, according to exemplary embodiments of the present invention. Hereinafter, the erase operation of the flash memory device will be more fully described with reference to accompanying drawings.

In the example depicted in FIG. 3, when an erase command CMD is received, the control logic 150 activates the pump enable signal PUMP_EN. The pump 141 begins a pumping operation to produce a bulk voltage in response to activation of the pump enable signal PUMP_EN. A detection signal DET may be activated when the generated bulk voltage is lower than a target voltage, and an oscillator 143 may generate an oscillation signal (causing the pump 141 to perform the pumping operation) during the active period of the detection signal DET. The bulk voltage may be supplied to a bulk area of a memory cell array 100. At the same time, the control logic 150 may control a row decoder circuit 110, so that word lines of a selected memory block are driven with an erase voltage (e.g., 0V).

When the bulk voltage reaches its target level, the detector 142 inactivates the detection signal DET. The oscillator 143 stops generating the oscillation signal in response to inactivation of the detection signal DET, causing the pump 141 to stop the pumping operation. At the same time, the erase controller 152 activates a timer enable signal TEN in response to inactivation of the detection signal DET, causing the timer 153 to initiate a fixed time period for the erasing operation. After the fixed time period elapses, the timer 153 activate a timer end signal TOUT. In response to activation of the timer end signal TOUT, the erase controller 152 inactivates the pump enable signal PUMP_EN. Thus, in response to the pump enable signal PUMP_EN being inactivated, the pump 141 is inactivated and, simultaneously, the bulk voltage supplied to the bulk area of the memory cell array 100 may be discharged. Accordingly, the erase operation is ended.

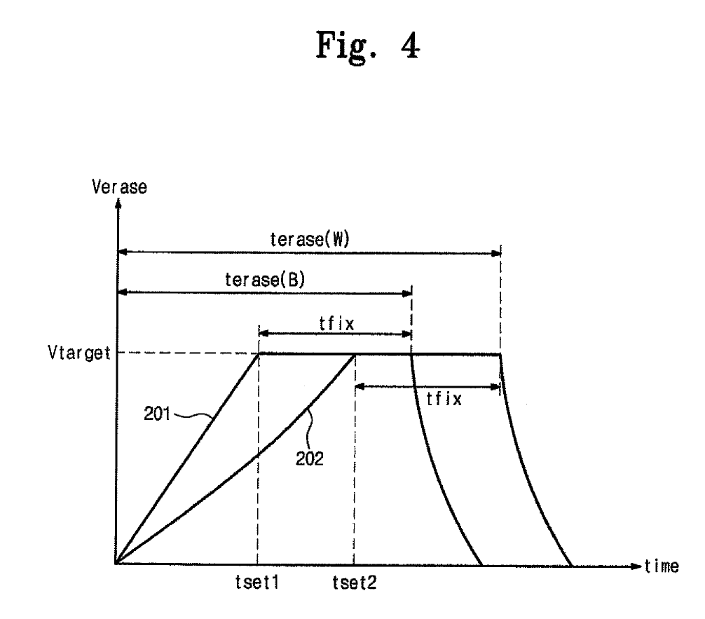

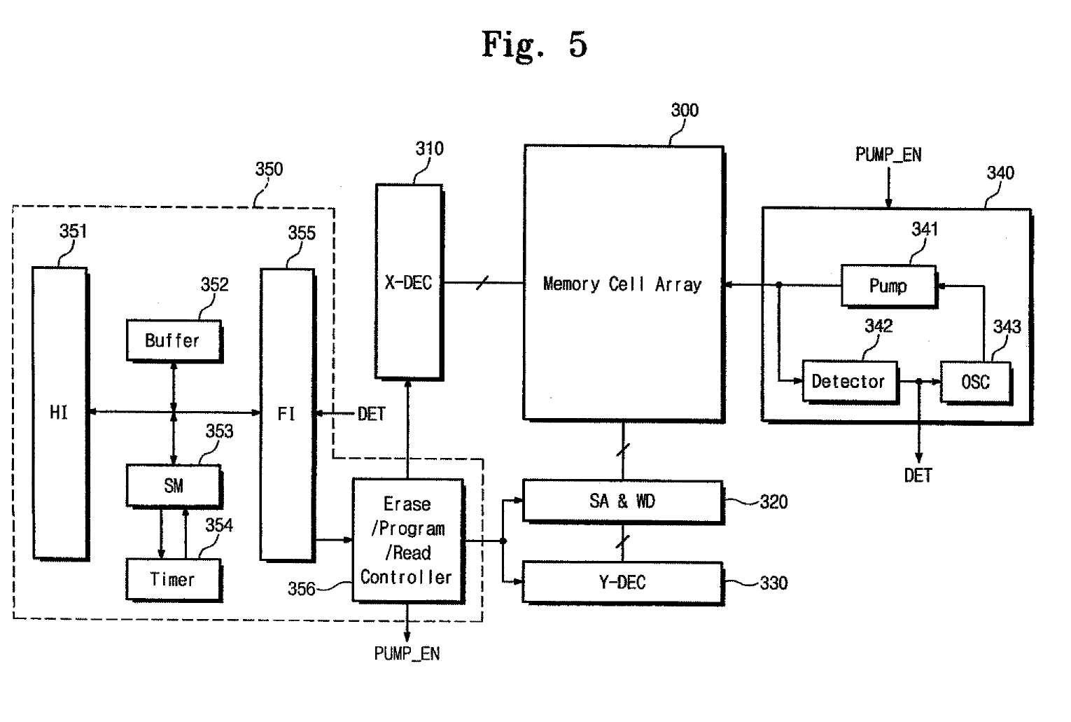

FIG. 4 is a diagram showing the variation of an erase voltage during an erase operation of a flash memory device, according to exemplary embodiments of the present invention.

The time required to increase a bulk voltage (or erase voltage) to a target voltage, i.e., a slope of the bulk voltage over time, may be determined differently in various flash memory devices. This may be caused by process, voltage and temperature variations, for example, as described above. Accordingly, flash memory devices of the present embodiments may be configured to not maintain a constant erase time, and may vary a bulk voltage according to a pumping capacity or an erase time or a slope.

For example, a slope indicated by 201 may be obtained by a first flash memory device having a relatively superior pumping capacity, and a slope indicated by 202 may be obtained by a second flash memory device having a relatively inferior pumping capacity. Therefore, slope 201 reaches the target voltage Vtarget in time tₛₑₜ₁, while slope 202 reaches the target voltage Vtarget in time tₛₑₜ₂, which is longer than time tₛₑₜ₁.

After the bulk voltage reaches the target voltage Vtarget and a certain time elapses (e.g., tfix), the bulk voltage may be discharged. Accordingly, as illustrated in FIG. 4, the respective erase times of the first and second flash memory devices are not maintained constantly, but are varied according to respective pumping capacities. It is thus possible to separately optimize the total erase time of each flash memory device. For example, the total erase time terase(B) corresponding to the first flash memory device having the superior pumping capacity is shorter than the total erase time terase(W) corresponding to the second flash memory device having the inferior pumping capacity.

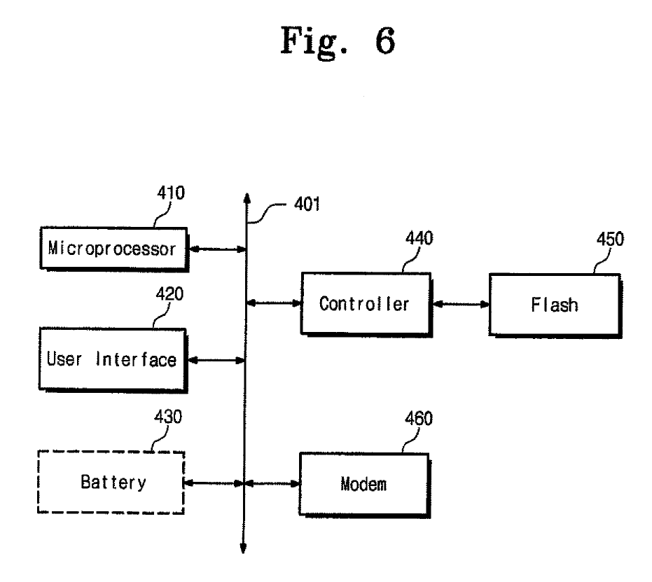

FIG. 5 is a block diagram of a flash memory device, according to other exemplary embodiments of the present invention.

The flash memory device illustrated in FIG. 5 may be a OneNAND flash memory device, for example, which may be configured to communicate with a host in a NOR interface manner and to perform a memory control function. The flash memory device illustrated in FIG. 5 may include a memory cell array 300, a row decoder circuit (X-DEC) 310, a sense amplifier and write driver circuit 320, a column decoder circuit (Y-DEC) 330, a bulk voltage generator circuit 340, and control logic 350. The memory cell array 300, the row decoder circuit 310, the sense amplifier and write driver circuit 320, the column decoder circuit 330, and the bulk voltage generator circuit 340 are substantially the same as those illustrated in FIG. 1, and thus the various descriptions will not be repeated.

The control logic 350 illustrated in FIG. 5 may include a host interface 351, a buffer 352, a state machine 353, a timer 354, a flash interface 355, and an erase/program/read controller 356. The host interface 351 provides an interface with a host (not shown), and the buffer 352 buffers data to be stored in the memory cell array 300. The state machine 353 is used as a scheduler, and activates a flag signal indicating an operation mode (e.g., an erase operation mode) in response to a command transferred via the host interface 351. Also, the state machine 353 activates the timer 354 in response to a detection signal DET transferred through the flash interface 355. The state machine 353 inactivates the flag signal indicating the operation mode when a timer end signal is provided by the timer 354.

The flag signal is provided to the erase/program/read controller 356 via the flash interface 356. The erase/program/read controller 356 is configured to control erase, program and/or read operations. More particularly, during an erase operation, the erase/program/read controller 356 controls the erase operation according to the flag signal provided via the flash interface 356.

As described with respect to FIG. 1, a pump enable signal PUMP_EN may be activated in response to activation of the flag signal (e.g., indicating an erase operation) from the state machine 353 and inactivated in response to inactivation of the flag signal. The state machine 353 may activate the timer 354 in response to the detection signal DET (indicating that the bulk voltage has reached the target voltage) and inactivate the flag signal after the timer 354 determines that a predetermined amount of time has elapsed. The erase/program/read controller 356 may terminate the erase operation in response to inactivation of the flag signal. Accordingly, it is possible to optimize an erase time of each flash memory device, e.g., according to a corresponding pumping capacity of the respective bulk voltage generator circuit 340.

A flash memory device is a kind of a nonvolatile memory device capable of maintaining data stored therein even when powered off. With rapidly increasing use of mobile apparatuses, such as cellular phones, personal digital assistants (PDA), digital cameras, global positioning systems (GPSs), portable gaming consoles, MP3 players and the like, flash memory devices are widely employed for code storage, as well as data storage. Flash memory devices may also be utilized for home and business applications, such as high-definition TVs, digital versatile disks (DVDs), routers, and the like.

FIG. 6 is a block diagram of an exemplary computing system, including a flash memory device of the disclosed embodiments. The computing system may include a microprocessor 410, a user interface 420, a modem 460 such as a baseband chipset, a memory controller 440, and a flash memory device 450, all of which are connected (directly or indirectly) to a bus 401. The flash memory device 450 may be configured substantially the same as the devices described above with respect to FIG. 1 or 5. In the flash memory device 450, N-bit data (where N is an integer greater than or equal to 1) to be processed by the processing unit 410 is stored through the memory controller 440. If the computing system shown in FIG. 6 is a mobile apparatus, a battery 460 may be further provided to supply an operation voltage of the computing system.

Although not shown in FIG. 6, the computing system may be further equipped with an application chipset, a camera image processor (e.g., CMOS image sensor; CIS), a mobile DRAM, etc., depending on the desired functionality. Further, the flash memory device 450 and the memory controller 440 may be configured to support a memory card type of implementation. The flash memory device 450 and the memory controller 440 may be substituted by a OneNAND flash memory device illustrated in FIG. 5, for example.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of erasing a flash memory device, comprising:
driving with a bulk voltage a bulk area of the flash memory device in which memory cells are formed;
detecting when the bulk voltage reaches a target voltage; and
terminating the driving of the bulk area following a time period after the bulk voltage reaches the target voltage.

2. The method of claim 1, further comprising:
driving word lines with an erase voltage.

3. The method of claim 2, wherein the bulk voltage is greater than the erase voltage.

4. A flash memory device comprising:
a memory cell array formed in a bulk area and comprising memory cells arranged in rows and columns;
a bulk voltage generator configured to supply a bulk voltage to the bulk area; and
a controller configured to control the bulk voltage generator to vary a total erase time based on a time required for the bulk voltage to reach a target voltage.

5. The flash memory device of claim 4, wherein the bulk voltage generator generates a detection signal indicating whether the bulk voltage reaches the target voltage.

6. The flash memory device of claim 5, wherein when the detection signal indicates that the bulk voltage has reached the target voltage, the controller controls the bulk voltage generator to stop supplying the bulk voltage to the bulk area after a predetermined time period.

7. The flash memory device of claim 6, wherein the controller comprises an erase controller for activating a pump enable signal in response to a flag signal indicating an erase operation, the bulk voltage generator operating to supply the bulk voltage in response to the pump enable signal.

8. The flash memory device of claim 7, wherein the controller further comprises a timer,
wherein the erase controller generates a timer enable signal in response to the detection signal, and the timer operates in response to the timer enable signal and generates a timer end signal after the predetermined time period; and
wherein the erase controller inactivates the pump enable signal in response to the timer end signal.

9. The flash memory device of claim 4, further comprising:
a row decoder circuit configured to control the rows under control of the controller, the row decoder circuit driving the rows with an erase voltage during an erase operation.

10. The flash memory device of claim 8, wherein the erase controller comprises a state machine.

11. The flash memory device of claim 8, wherein the erase controller comprises a buffer for temporarily storing data to be stored in the memory cell array.

12. The flash memory device of claim 4, wherein the flash memory device comprises one of a NAND flash memory device or a OneNAND flash memory device.

13. A memory card comprising:
a flash memory device; and
a memory controller configured to control the flash memory device,
wherein the flash memory device comprises:
a memory cell array formed in a bulk area and including memory cells arranged in rows and columns;
a bulk voltage generator configured to supply a bulk voltage to the bulk area; and
control logic configured to control the bulk voltage generator to vary an erase time based on a time required for the bulk voltage to reach a target voltage.

14. The flash memory device of claim 13, wherein the bulk voltage generator activates a detection signal when it begins supplying the bulk voltage and inactivates the detection signal when the bulk voltage reaches the target level.

15. The flash memory device of claim 14, wherein the control logic controls the bulk voltage generator to stop supplying the bulk voltage to the bulk area following a predetermined time period after the detection signal is inactivated.

16. The flash memory device of claim 15, wherein the control logic comprises an erase controller for activating a pump enable signal in response to a flag signal indicating an erase operation, the bulk voltage generator operating to supply the bulk voltage in response to the pump enable signal.

17. The flash memory device of claim 16, wherein the control logic further comprises a timer,
wherein the erase controller generates a timer enable signal in response to the detection signal being inactivated, and the timer operates in response to the timer enable signal and generates a timer end signal after the predetermined time period; and
wherein the erase controller inactivates the pump enable signal in response to the timer end signal.

18. The flash memory device of claim 13, further comprising:
a row decoder circuit configured to control the rows under control of the control logic, the row decoder circuit driving the rows with an erase voltage during an erase operation.

19. The flash memory device of claim 16, wherein the erase controller comprises a state machine.

20. The flash memory device of claim 16, wherein the erase controller comprises a buffer for temporarily storing data to be stored in the memory cell array.
